(19) United States
(12) Patent Application Publication
(10) Pub. No.: US 2010/0139550 A1
(43) Pub. Date: Jun. 10, 2010

(54) CRUCIBLE FOR PROCESSING A HIGH-MELTING MATERIAL AND METHOD OF PROCESSING SAID MATERIAL IN SAID CRUCIBLE

(76) Inventors: Tilo Aichele, Jena (DE); Christoph Gross, Frankfurt am Main (DE); Lutz Parthier, Kleinmachnow (DE)

Correspondence Address: MICHAEL J. STRIKER, 103 EAST NECK ROAD, HUNTINGTON, NY, 11743, US

(21) Appl. No.: 12/629,328

(22) Filed: Dec. 2, 2009

(30) Foreign Application Priority Data
Dec. 4, 2008 (DE) 10 2008 060 520.4

(51) Int. Cl. C30B 15/10; B32B 37/00; C30B 15/00; C30B 11/00

(52) U.S. Cl. 117/35; 117/206; 156/293; 117/73

(57) ABSTRACT

The crucible for receiving a melt of a high-melting material has a refractory metal layer that has a melting point of at least 1800° C., which covers a part of the surface of the crucible that would otherwise come in contact with the melt. The refractory metal preferably has a thickness of less than 1 mm. It is either a coating deposited on the surface of the crucible or is a loosely connected foil applied to the surface of the crucible.

### CROSS-REFERENCE

The invention described and claimed herein below is also described in German Patent Application No. 10 2008 060 520.4, filed on Dec. 4, 2008. This German Patent Application provides the basis for a claim of priority of invention for the crucible and method claimed herein below under 35 U.S.C. 119 (a)-(d).

### BACKGROUND OF THE INVENTION

1. The Field of the Invention

The present invention relates to a crucible and method for processing a high-melting material in this crucible and also to its uses.

2. The Related Art

The processing of high-melting materials, especially the purification of high-melting material or the production of single crystals of high-melting material, is of significance in semiconductor technology and for the manufacture of optical elements for microlithography.

EP-A 1 701 179 discloses a method of making optical elements for microlithography, with which lens systems are obtainable and their uses.

The processing of high-melting materials can occur in crucibles or without crucibles.

Crucible-free zone refining is a known procedure used in semiconductor engineering. The purification of raw materials usually occurs prior to the growth of semiconductor crystals for wafer manufacture. In this procedure a vertically extending rod of starting material is locally melted and the melted zone is repeatedly guided through the rod, wherein the impurities are concentrated at the beginning or the end of the rod according to the types of impurities. The melt zone is generally produced inductively. Because of the comparatively high viscosity of the semiconductor melt suitable selection of the inductor geometry permits the melt zone between the solid rod pieces to be maintained without crucible contact even in rods with large diameters.

The crucible-free zone melting procedure is also used for purification of high-melting oxide materials, such as sapphire. The melt zone is chiefly produced by a mirror heater and also very intense and focused light. Furthermore it is also known to produce the melt zone with laser light or electron bombardment, or by resistive heating, or by a combination of resistive and inductive heating. It is common to all technologies that only a very small melt zone of a high-melting oxide can be maintained because of the very low viscosity of its melt. The Czochralski process using metal crucibles is preferred for growing single crystals of high-melting oxides. However the Verneuil growth process, the skull melting process, and growth processes in crucibles, such as the VGF process (Vertical gradient freeze process) or the HEM process (modified VGF process) are also used.

The melt zone is produced inductively during crucible-free zone refining of semiconductor rods with large diameters. The high viscosity of the melt permits vertical guidance of the melt zone without crucible contact. Because of its extremely low conductivity high-melting oxide material cannot be melted with only inductive heating. Other techniques for producing the melt zone except for resistive heating, such as heating with a mirror heater, laser or electron beam, are not suitable for producing the melt zone since the energies that can be input by them are too small. Furthermore the melt zone cannot be maintained between the rod pieces in the case of rods of high-melting oxide material with large diameters because of its low viscosity. The growth of single crystals, or polycrystals, of high-melting oxide material occurs for example according to the VGF or HEM processes in metal crucibles, or according to the Czochralski process from a metal crucible. That the melt, or the melt and the crystal, is or are in contact with a crucible so that impurities from the crucible can build up in the crystal is common to all these methods.

The growing crystals experience huge temperature gradients and resulting high internal stresses during crucible-free growth methods, such as the Verneuil process and the skull-melting process.

The purification or growth of large-sized single crystals of high-melting oxide materials of lithographic quality requires a method for rods with large diameters and the highest purities. Especially the single crystal should be as stress-free as possible. The crucible-free methods are out of the question. Furthermore in order to avoid further contamination from the outside during purification of the material contact with the crucible, heater, or other apparatus components is also out of the question. However the purification must occur in a so-called boat because of the specific properties of the melt zone associated with the required sizes of the rod and the melt zone. The term “boat” means a special embodiment of a crucible. The melt zone is ordinarily produced by resistance heating.

Contact with the crucible may also not be avoided during growth of high purity stress-free single crystals. In order to avoid or minimize the contamination of the rod or the crystal by the crucible, a crucible comprising high purity material must be used. Thus no cold forming process can be used to make the crucible. Since the rod or the crystal adheres to the crucible during the growth process in the crystal, the rod or the crystal must be mechanically separated from the boat or the crystal. In each case rod residue, crystal residue or melt residue must be cleaned from the boat or the crucible. As a result, impurities are again introduced into the high purity crucible, the rod or the crystal by the tools used to clean the boat or the crucible.

The manufacture of suitable large, high purity refractive metal crucibles is laborious, tedious and expensive. As a generally rule, these crucibles have less mechanical stability for bearing the mechanical stress and strain from the weight of the melt material and from the purification process than crucibles made by cold forming. They undergo substantially higher wear. The purification of high-melting oxides or growth of their large-sized single crystals with high purity, e.g. for lithographic applications, requires a method performed in a high purity crucible with sufficient mechanical stability, in which a rod, a crystal, or a melt residue may be separated by mechanical treatment or handling of the crucible easily, and without the currently occurring disadvantages.

The known crucibles are laboriously manufactured, e.g. by welding process or by deposition processes, especially by electrolytic deposition on a negative mold. Crucibles made in this manner, especially those, which are made by deposition processes, are frequently not always leak-tight and are characterized frequently by leakage when used over and over again.

Especially in the known methods for single crystal growth of high-melting materials the problem frequently occurs that the required crucible adheres to the grown crystal and the crucible material reacts with the melt of the high-melting material.

### SUMMARY OF THE INVENTION

It is an object of the present invention to provide a crucible, which is suitable for processing of a high-melting material, and at least partially overcomes the above-described disadvantages of the crucibles known in the prior art for this purpose.

This object is attained by a crucible for receiving a melt of a high-melting material, in which the part of the surface of the crucible, which comes in contact with the melt, is coated or covered with a layer, which comprises a metal with a melting point of at least 1800° C. This crucible is the subject matter of the present invention.

Preferably the layer is a foil or a layer rigidly connected to the crucible material.

Preferably the interior part of the crucible is completely covered with the foil.

The foil is preferably loosely connected with the remaining part of the crucible. The term “loosely connected” means that, after melting and solidification of a high-melting material in the crucible, the solidified, high-melting material bonded to the foil during solidification can be removed from the crucible with the foil adhering to it and thus released from the remaining part of the crucible, i.e. from the supporting crucible.

The metal of the layer coating or covering the part of the surface of the crucible coming in contact with the melt is preferably a refractory metal. The refractory metal is especially a metal selected from the group consisting of hafnium, niobium, tantalum, molybdenum, tungsten, ruthenium, rhenium, osmium, iridium and alloys of the aforesaid metals.

The foil of the crucible according to the invention has a preferred thickness of less than 1 mm, especially less than 0.1 mm, and especially preferably less than 0.05 mm.

The minimum thickness of the foil preferably amounts to at least 0.001 mm.

The crucible according to the invention comprises the foil and a remaining part of the crucible, designated a supporting crucible herein, which acts as a support for the foil. The supporting crucible preferably comprises a refractory metal. It can be made by cold forming methods, such as turning on a lathe, deep drawing, etc. The remaining part of the crucible acting as a support preferably comprises a less pure material than that of the foil. The crucible according to the invention also has the advantage that the high-melting material does not come into direct contact with the supporting crucible and cannot be contaminated by it.

In a further preferred embodiment the layer is rigidly attached with the crucible material.

One such layer is preferably obtained by vapor deposition or preferably by an electrochemical deposition. Typical chemical depositions are obtained by galvanizing.

The subject matter of the present invention also includes a process for making the crucible according to the invention comprising coating the supporting crucible with the layer or applying the foil to the supporting crucible.

The subject matter of the present invention further comprises a method of using the crucible according to the present invention for processing a high-melting material.

The phrase “processing of high-melting material” especially means the manufacture of single crystals from high-melting material. It can also mean the purification of a single crystal made from the high-melting material, in which the high-melting material can be obtained even in the form of a polycrystalline material. In each case the processing of the high-melting material is such that at least one part of it is melted.

A further subject matter according to the present invention is a process for processing a high-melting material comprising introducing the high-melting material into a crucible with the foil according to the invention, the at least partial melting of the high-melting material, the solidification of the melted high-melting material in the crucible with the foil, the removal of the high-melting material together with the foil from the crucible and the removal of the foil from the high-melting material.

The removal of the high-melting material together with the foil from the crucible can occur e.g. by overturning or toppling the crucible so that both drop out of the crucible.

It is preferable to select a crucible for the method, in which the foil has a melting point, which is at least 1-times, 3-times, or 4-times, especially at least 1.5-times, the melting point of the high-melting material in degrees Centigrade.

Furthermore it is preferable to select a crucible for the method, in which the remaining part of the crucible, i.e. the supporting or base crucible, has a melting point that is at least 1-times, 1.5-times, or 3-times, especially at least 4-times, the melting point of the high-melting material in degrees Centigrade.

The removal of the foil from the high-melting material (e.g. from a single crystal made from the high-melting material) can occur without great mechanical labor, e.g. by exfoliation or by pulling off. When the foil comprises combustible material that burns by heating in an oxygen containing atmosphere, it is also possible to remove the foil from the high-melting material by burning it off or by combustion. For example, tungsten, tantalum, or niobium is this sort of material. In a further preferred embodiment the foil is formed from a material that dissolves in an acid or base. In this case it is also possible to etch the foil away from the high-melting material. For example, a tungsten foil may be dissolved in chromic acid.

This is an especially easy to handle variant of the method according to the invention.

The foil can be made, e.g., by deposition in a negative mold. It can also be provided in the crucible by welding.

Because of the small thickness of the foil it can be made more rapidly with less material expenses and thus more economically than a complete crucible comprising high purity material. Thus the foil can also be provided for one-time usage. Thus e.g. in a Czochralski process (however other processes can also be considered) a constant purity of the foil, which comes into contact with the high-melting material, can be guaranteed.

Those foil materials are preferably selected according to the invention, in which no or only very little diffusion of foil material into the melt of high-melting material occurs. It is preferable that the foil material is selected so that the high-melting material contains less than 100 ppm, especially less than 10 ppm, and especially particularly less than 1 ppm of foil material after performing the method according to the present invention.

The material for the remaining part of the crucible must be selected from materials that do not attack the material that is used to make the foil. For example, ceramic material can also be used for the remaining part of the crucible.

Also a comparatively soft material can be used for the foil, because the remaining part of the crucible, the supporting crucible, acts to provide mechanical support.

It is advantageous to select the material for the foil and for the remaining part of the crucible so that a reaction (e.g. eutectic formation, peritectic formation, or alloy formation) does not occur during the performing of the method according to the present invention.

The crucible according to the invention also has the advantage that contact between the remaining part of the crucible and high-melting material is avoided so that e.g. undesired reactions between the material of the remaining part of the crucible and the high-melting material are avoided.

The method according to the invention can, e.g., be used for growing sapphire (e.g. according to the so-called float zone process) or for growing oxidic garnets or for their purification. Single crystals or polycrystals can be grown. The method can be applied according to the VGF growth process, the VB growth process, the HB growth process, the HEM growth process, or another process.

According to the invention the remaining part of the crucible, i.e. the supporting crucible, e.g. can be made by turning on a lathe from leak-proof or dense sintered material. It can also be made by welding rolled metal sheet or plates.

The remaining part of the crucible, which serves only as a mechanical supporting crucible, can be repeatedly used by the method of the invention. It can comprise an inexpensive less pure material. It is also not necessary to make the entire crucible from an expensive high purity material as in the methods of the state of the art. According to the invention even simple forged crucibles, for example made of molybdenum, can be used.

Typical crucible materials are the same as the materials that are used for the foil or the coating. However other materials stable at the working temperatures, such as the ceramic materials Al₂O₃, ZrO₂, Y₂O₃ and MgO, are also useful.

The foils can also be made by a deposition process. They can be made so that they are highly pure and hermetically sealed, i.e. leak-proof.

The temperature of the melt of the high-melting material customarily amounts to no more than 2100° C. when the method according to the invention is performed. Up to these temperatures no bonding of the remaining part of the crucible to the foil occurs, especially when both are made from tungsten or molybdenum. Generally attention is given to the selection of materials for the foil and the remaining part of the crucible so that both materials are bonded to each other as little as possible.

The foil can even be made from a metal, which does not have a very high mechanical stability at the temperatures used. For example, it can be made of iridium. The foil can be mechanically supported sufficiently e.g. by a remaining crucible made from a ceramic material, such as yttrium oxide.

The method according to the invention can be used for Czochralski growth of sapphire or of oxidic garnet. For example, resistive heating can be used. E.g. a high purity iridium foil can be used as the foil. The supporting crucible for the foil can be a ceramic material.

The process according to the invention can be used for the growth of single crystals. However it can also be used for making polycrystalline materials.

The high-melting materials, which are used in the method according to the present invention, are preferably those with a melting point of over 1800° C.

In a further preferred embodiment according to the invention the high-melting materials are oxidic materials, such as e.g. sapphire.

However the high-melting material can even be a metal, which has the above-described properties.

Preferably the foil material for a given high-melting material is selected so that both materials do not react and form no alloys during the performance of the method according to the invention.

Typical high-melting materials are, for example, described in EP-A 1 701 179 and can especially be cubic garnets, cubic spinels, cubic perovskites and/or cubic II/IV oxides.

Preferably the cubic garnets are especially yttrium-aluminum garnet, Y₃Al₅O₁₂; lutetium-aluminum garnet, (LuAG), Lu₃Al₅O₁₂; grossular, Ca₃Al₂Si₃O₁₂; elpasolith, K₂NaAlF₆; K₂NaScF₆; K₂LiAlF₆; and/or cryolithionite, Na₃Al₂Li₃F₁₂. Additional suitable garnets are Tm₃Al₅O₁₂, Sc₃Al₅O₁₂, Dy₃Al₅O₁₂, and YbAl₅O₁₂.

Additional suitable high-melting materials especially include cubic garnets, such as the above-mentioned Y₃Al₅O₁₂ (YAG) or Lu₃Al₅O₁₂ (LuAG), in which yttrium or lutetium are replaced by ions of the same valence and with a comparable ionic radius.

Furthermore the high-melting materials can also be cubic garnets of the general formula (I):

(A₁₋ₓDₓ)₃Al₅O₁₂ (I)

in which D is an element of similar valence and ionic radius to A⁺³, in order to have as little lattice deformation as possible. According to the invention the preferred elements for A are especially yttrium, rare earths or lanthanides, such as Ce, Pr, Nd, Pm, Sm, Eu, Gd, Tb, Dy, Ho, Er, Tm, Yb, Lu, and Sc. However Y, Lu, Yb, Tm, Dy, and Sc are especially preferred. Suitable representatives of the doping agent D are similarly selected from the group including yttrium, rare earths and scandium. Garnets of the type Y₃Al₅O₁₂, Lu₃Al₂O₁₂, Dy₃Al₅O₁₂, Tm₃Al₅O₁₂, Yb₃Al₅O₁₂, which are doped with other rare earths and/or Sc, and especially a mixed crystal comprising (Y₁₋ₓLuₓ)₃Al₅O₁₂, have proven to be especially suitable.

The parameter x in formula (I) means the mol fraction, and 0≦x≦1. Preferably A and D are different from each other. For the case in which A and D are the same, x=0. According to the invention those mol fractions are used, which are the same for the melt and the crystal, which means those mol fractions for which the percentage composition does not change during crystallization.

Of the cubic spines especially spinel MgAl₂O₄, ghanospinel (Mg, Zn)Al₂O₄, CaAl₂O₄, CaB₂O₄ and/or lithium spinel LiAl₅O₈ have proven to be especially suitable.

BaZrO₃ and/or CaCeO₃ are especially preferred cubic perovskites. (Mg, Zn)O has proven to be an especially suitable cubic II/IV oxide.

Large-volume single crystals, which have a diameter greater than 150 mm, especially greater than 200 mm, more especially greater than 250 mm and particularly especially greater than 300 mm, can be made by the method according to the invention.

Single crystals for optical elements and for optical imaging systems can be made by the methods according to the present invention. These single crystals are suitable for making steppers, lasers, especially excimer lasers, computer chips and integrated circuits and electronic devices, which contain the circuits and chips.

### BRIEF DESCRIPTION OF THE DRAWING

The objects, features and advantages of the invention will now be illustrated in more detail with the aid of the following description of the preferred embodiments, with reference to the accompanying figures in which:

FIG. 1 is a diagrammatic cross-sectional view through a first embodiment of the crucible according to the present invention in which the surface in contact with the melt of the high-melting material is provided by a coating on the interior side of the crucible; and

FIG. 2 is a diagrammatic cross-sectional view through a second embodiment of the crucible according to the present invention in which the surface in contact with the melt of the high-melting material is provided by a foil arranged in the crucible.

### DESCRIPTION OF THE PREFERRED EMBODIMENTS

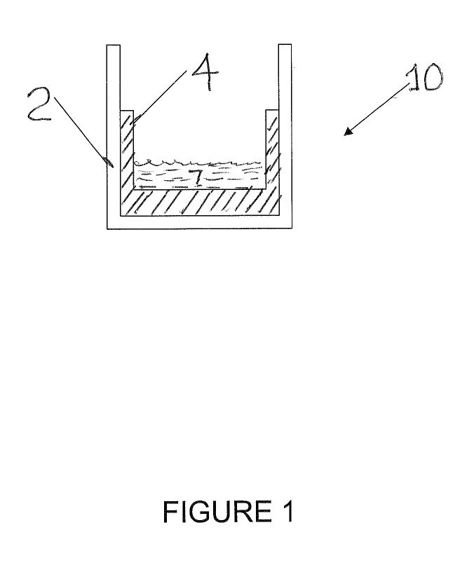

FIG. 1 illustrates a first embodiment of a crucible 10 according to the present invention. The crucible 10 comprises a supporting crucible or supporting body 2 and a coating 4 on the interior surface of the supporting crucible or supporting body. The crucible 10 contains a melt 7 of a high-melting material. The coating 4 provides the only surface in contact with the melt 7 and protects the surfaces of the supporting crucible 2 from contact with the melt 7. The coating 4 is preferably a refractory metal, for example indium, and the supporting crucible may be made of ceramic material as indicated above.

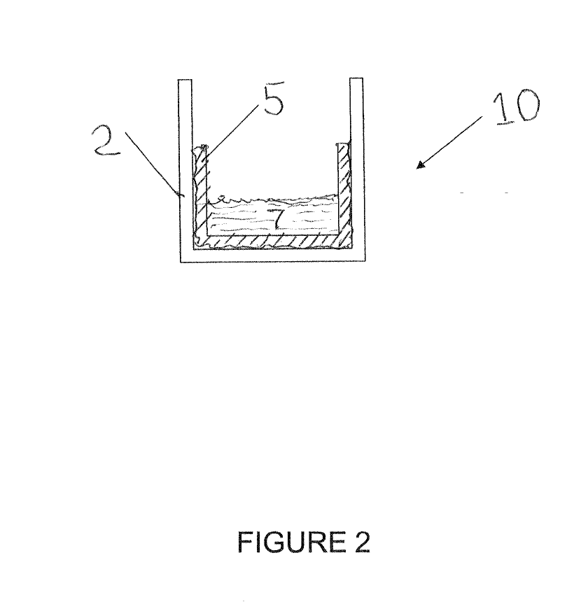

FIG. 2 illustrates a second embodiment of a crucible 10 according to the present invention. The crucible 10 comprises a supporting crucible or supporting body 2. Instead of the coating 4 in the embodiment shown in FIG. 1 the crucible 10 has a foil 5 placed in the interior of the crucible, so that it covers the interior surface of the crucible. The foil 5 is formed and arranged in the crucible so that it provides the only surface in contact with the melt 7 and protects the surfaces of the supporting crucible 2 from contacting the melt 7. The supporting crucible can be a ceramic material and the foil 5 can be made of a refractory metal, such as tungsten.

While the invention has been illustrated and described as embodied in a crucible for processing a high-melting material and a method of processing the high-melting material in the crucible, it is not intended to be limited to the details shown, since various modifications and changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed is new and is set forth in the following appended claims.

We claim:

1. A crucible for receiving a melt of a high-melting material, said crucible consisting of a remaining part and a layer arranged on the remaining part so that the melt only comes into contact with the layer when the melt is received in the crucible;
wherein said layer does not react with said melt and is made of a metal with a melting point of at least 1800° C.

2. The crucible as defined in claim 1, wherein said metal of said layer is a refractory metal.

3. The crucible as defined in claim 1, wherein said layer is a foil and said foil has a thickness less than 1 mm.

4. The crucible as defined in claim 3, wherein said foil is loosely connected with said remaining part of the crucible.

5. The crucible as defined in claim 4, wherein said remaining part is made of a metal with a melting point of at least 1800° C.

6. The crucible as defined in claim 5, wherein said metal of said remaining part is a refractory metal.

7. A method of making a crucible for receiving a melt of a high-melting material, said method comprising the step of lining a surface of a supporting crucible with a foil or arranging the foil on the surface of the supporting crucible, so that said melt formed of said high-melting material only comes in contact with said foil when said melt is received in said crucible;
wherein said foil does not react with the melt, is made of a refractory metal with a melting point of at least 1800° C., and has a thickness of less than 1 mm; and
wherein said supporting crucible is a remaining part of said crucible for receiving said melt of said high-melting material and is also made of a refractory metal with a melting point of at least 1800° C.

8. A method of processing a high-melting material, especially for making optical materials, said method comprising the step of using a crucible according to claim 1.

9. A method of processing a high-melting material, said method comprising
a) introducing a high-melting material into a crucible, said crucible consisting of a remaining part and a foil arranged on the remaining part so that a melt of the high-melting material only comes into contact with the foil when the melt of the high-melting material is received in the crucible, wherein said foil does not react with said melt and is made of a metal with a melting point of at least 1800° C.;
b) at least partially melting the high-melting material to form the melt;
c) solidifying the at least partially melted high-melting material in the crucible to form a solidified material;
d) removing the solidified material together with the foil from the crucible; and then
e) removing the foil from the solidified material.

10. The method as defined in claim 9, further comprising growing a single crystal of the high-melting material.

11. The method as defined in claim 10, further comprising a Czochralski process, a VGF process, or an HEM process for growing the single crystal.

12. The method as defined in claim 9, wherein said melting point of said foil is at least 1.4 times a melting point of the high-melting material in degrees Centigrade.

13. The method as defined in claim 9, wherein said high-melting material is a sapphire.

14. The method as defined in claim 9, wherein said high-melting material is selected from the group consisting of cubic garnets, cubic spinels, cubic perovskites and cubic II/IV oxides.

15. The method as defined in claim 9, wherein said high-melting material is a cubic garnet of the formula (I):
(A₁₋ₓDₓ)₃Al₅O₁₂ (I),
wherein A is selected from the group consisting of Y, Ce, Pr, Nd, Pm, Sm, Eu, Gd, Tb, Dy, Ho, Er, Tm, Yb, Lu and Sc;
wherein D, independently of A, is likewise selected from the group consisting of Y, Ce, Pr, Nd, Pm, Sm, Eu, Gd, Tb, Dy, Ho, Er, Tm, Yb, Lu and Sc, but A and D are different; and
wherein 0≦x≦1.
